(19) United States
(12) Patent Application Publication
(10) Pub. No.: US 2026/0329185 A1
(43) Pub. Date: Oct. 22, 2026

(54) METROLOGY TARGET

(71) Applicant: ASML Netherlands B.V., Veldhoven (NL)

(72) Inventors: Patrick WARNAAR, Tilburg (NL); Maurits VAN DER SCHAAR, Eindhoven (NL); Xiang HU, Shenzhen (CN); Olger Victor ZWIER, Eindhoven (NL); Henricus Wilhelmus Maria VAN BUEL, 's-Hertogenbosch (NL)

(73) Assignee: ASML Netherlands B.V., Veldhoven (NL)

(21) Appl. No.: 19/486,795

(22) PCT Filed: May 7, 2024
(86) PCT No.: PCT/EP2024/062610

§ 371 Date: Nov. 21, 2025

Related U.S. Application Data
(63) Continuation of application No. PCT/CN2023/102862, filed on Jun. 27, 2023.

(51) Int. Cl. G03F 7/00; G01B 11/27; G03F 1/22

(52) U.S. Cl. CPC G03F 7/70683; G01B 11/272; G03F 1/22; G03F 7/70633

(57) ABSTRACT

Disclosed is a method of metrology, comprising: obtaining metrology data relating to measurement of a target comprising at least a first grating in a first layer and a second grating in a second layer, wherein the first grating has a first chirped pitch starting with a first starting pitch and the second grating has a second chirped pitch starting with a second starting pitch, the first grating and second grating substantially overlapping, and the first chirped pitch and second chirped pitch being different, so as to generate at least one parameter of interest dependent Moiré-pitch when measured. A parameter of interest is determined from said at least one parameter of interest dependent Moiré-pitch described in said metrology data.

### CROSS-REFERENCE TO RELATED APPLICATIONS

This application claims priority of WO application PCT/CN2023/102862 which was filed on 27 Jun. 2023 and which is incorporated herein in its entirety by reference.

### FIELD OF THE INVENTION

The present invention relates to methods and apparatus for metrology usable, for example, in the manufacture of devices by lithographic techniques and to methods of manufacturing devices using lithographic techniques.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. In lithographic processes, it is desirable frequently to make measurements of the structures created, e.g., for process control and verification. Various tools for making such measurements are known, including scanning electron microscopes, which are often used to measure critical dimension (CD), and specialized tools to measure overlay, a measure of the accuracy of alignment of two layers in a device. Overlay may be described in terms of the degree of misalignment between the two layers, for example reference to a measured overlay of 1 nm may describe a situation where two layers are misaligned by 1 nm.

Recently, various forms of scatterometers have been developed for use in the lithographic field. These devices direct a beam of radiation onto a target and measure one or more properties of the scattered radiation—e.g., intensity at a single angle of reflection as a function of wavelength; intensity at one or more wavelengths as a function of reflected angle; or polarization as a function of reflected angle—to obtain a “spectrum” from which a property of interest of the target can be determined. Determination of the property of interest may be performed by various techniques: e.g., reconstruction of the target by iterative approaches such as rigorous coupled wave analysis or finite element methods; library searches; and principal component analysis.

The targets used by conventional scatterometers are relatively large, e.g., 40 μm by 40 μm, gratings and the measurement beam generates a spot that is smaller than the grating (i.e., the grating is underfilled). This simplifies mathematical reconstruction of the target as it can be regarded as infinite. However, in order to reduce the size of the targets, e.g., to 10 μm by 10 μm or less, e.g., so they can be positioned in amongst product features, rather than in the scribe lane, metrology has been proposed in which the grating is made smaller than the measurement spot (i.e., the grating is overfilled). Typically such targets are measured using dark field scatterometry in which the zeroth order of diffraction (corresponding to a specular reflection) is blocked, and only higher orders processed. Examples of dark field metrology can be found in international patent applications WO 2009/078708 and WO 2009/106279 which documents are hereby incorporated by reference in their entirety. Further developments of the technique have been described in patent publications US20110027704A, US20110043791A and US20120242940A. The contents of all these applications are also incorporated herein by reference. Diffraction-based overlay using dark-field detection of the diffraction orders enables overlay measurements on smaller targets. These targets can be smaller than the illumination spot and may be surrounded by product structures on a wafer. Targets can comprise multiple gratings which can be measured in one image.

In the known metrology technique, overlay measurement results are obtained by measuring the target twice under certain conditions, while either rotating the target or changing the illumination mode or imaging mode to obtain separately the −1st and the +1st diffraction order intensities. The intensity asymmetry, a comparison of these diffraction order intensities, for a given target provides a measurement of target asymmetry, that is asymmetry in the target. This asymmetry in the target can be used as an indicator of overlay (undesired misalignment of two layers). Another known method measures a phase difference between dark-field images of two different types of sub-target.

Although the known dark-field image-based overlay measurements are fast and computationally very simple (once calibrated), they use targets comprising only one or two constituent pitches. This means that, should the diffraction from the target diffract to an angle coinciding with aberrations an imperfections in the optical system, for example, the inferred parameter of interest value will be impacted.

It is therefore desirable to improve the accuracy of such parameter of interest measurements.

### SUMMARY

In a first aspect of the invention there is provided a method of metrology, comprising: obtaining metrology data relating to measurement of a target comprising at least a first grating in a first layer and a second grating in a second layer, wherein the first grating has a first chirped pitch starting with a first starting pitch and the second grating has a second chirped pitch starting with a second starting pitch, the first grating and second grating substantially overlapping, and the first chirped pitch and second chirped pitch being different, so as to generate at least one parameter of interest dependent Moiré-pitch when measured; determining a parameter of interest from said at least one parameter of interest dependent Moiré-pitch described in said metrology data.

In a second aspect of the invention there is provided a substrate comprising: at least one target; wherein each said at least one target comprises: at least a first grating in a first layer and a second grating in a second layer, wherein the first grating has a first chirped pitch starting with a first starting pitch and the second grating has a second chirped pitch starting with a second starting pitch, the first grating and second grating substantially overlapping, and the first chirped pitch and second chirped pitch being different, so as to generate at least one parameter of interest dependent Moiré-pitch when measured.

In another aspect a computer program comprising processor readable instructions which, when run on suitable processor controlled apparatus, cause the processor controlled apparatus to perform the method of the first or second aspect and a computer program carrier comprising such a computer program. The processor controlled apparatus may comprise a metrology apparatus or lithographic apparatus or processor therefor.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example only, with reference to the accompanying drawings in which:

FIG. 1 depicts a lithographic apparatus according to an embodiment of the invention;

FIG. 2 depicts a lithographic cell or cluster according to an embodiment of the invention;

FIG. 3(a) comprises a schematic diagram of a dark field scatterometer for use in measuring targets according to embodiments of the invention using a first pair of illumination apertures; FIG. 3(b) illustrates a detail of diffraction spectrum of a target grating for a given direction of illumination; FIG. 3(c) illustrates a second pair of illumination apertures providing further illumination modes in using the scatterometer for diffraction based overlay measurements; and FIG. 3(d) illustrates a third pair of illumination apertures combining the first and second pair of apertures;

FIG. 4 depicts a known form of multiple grating target and an outline of a measurement spot on a substrate;

FIG. 5 depicts a multiple grating target formed of two sub-targets where the constituent gratings each have a chirped pitch;

FIG. 6 is a plot of grating pitch against target position for each of two gratings of a target according to a first target embodiment;

FIG. 7 is a plot of Moiré-pitch against target position for a target according to an embodiment, in the presence of various overlay;

FIG. 8 is a representation of a measured signal obtained by measuring a target according to an embodiment; and

FIG. 9 is a plot of grating pitch against target position for each of three gratings of a target according to a second target embodiment.

### DETAILED DESCRIPTION OF EXEMPLARY EMBODIMENTS

Before describing embodiments of the invention in detail, it is instructive to present an example environment in which embodiments of the present invention may be implemented.

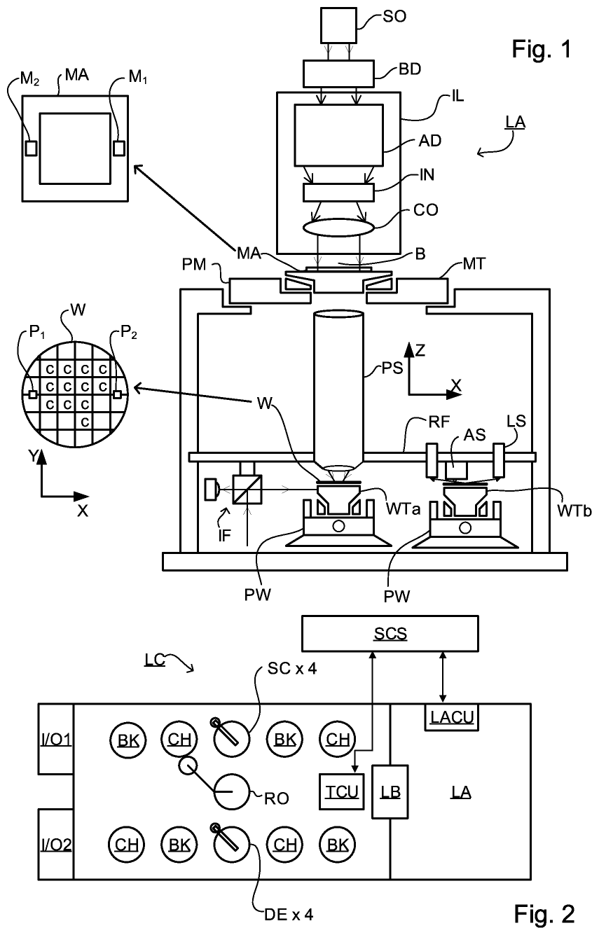

FIG. 1 schematically depicts a lithographic apparatus LA. The apparatus includes an illumination optical system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; a substrate table (e.g., a wafer table) WT constructed to hold a substrate (e.g., a resist coated wafer) W and connected to a second positioner PW configured to accurately position the substrate in accordance with certain parameters; and a projection optical system (e.g., a refractive projection lens system) P S configured to project a pattern imparted to the radiation beam B by patterning device MA onto a target portion C (e.g., including one or more dies) of the substrate W.

The illumination optical system may include various types of optical components, such as refractive, reflective, magnetic, electromagnetic, electrostatic or other types of optical components, or any combination thereof, for directing, shaping, or controlling radiation.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support may be a frame or a table, for example, which may be fixed or movable as required. The patterning device support may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table MT), and is patterned by the patterning device. Having traversed the patterning device (e.g., mask) MA, the radiation beam B passes through the projection optical system PS, which focuses the beam onto a target portion C of the substrate W, thereby projecting an image of the pattern on the target portion C. With the aid of the second positioner PW and position sensor IF (e.g., an interferometric device, linear encoder, 2-D encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment markers may also be included within dies, in amongst the device features, in which case it is desirable that the markers be as small as possible and not require any different imaging or process conditions than adjacent features. The alignment system, which detects the alignment markers is described further below.

Lithographic apparatus LA in this example is of a so-called dual stage type which has two substrate tables WTa, WTb and two stations—an exposure station and a measurement station-between which the substrate tables can be exchanged. While one substrate on one substrate table is being exposed at the exposure station, another substrate can be loaded onto the other substrate table at the measurement station and various preparatory steps carried out. The preparatory steps may include mapping the surface control of the substrate using a level sensor LS and measuring the position of alignment markers on the substrate using an alignment sensor AS. This enables a substantial increase in the throughput of the apparatus.

The depicted apparatus can be used in a variety of modes, including for example a step mode or a scan mode. The construction and operation of lithographic apparatus is well known to those skilled in the art and need not be described further for an understanding of the present invention.

As shown in FIG. 2, the lithographic apparatus LA forms part of a lithographic system, referred to as a lithographic cell LC or a lithocell or cluster. The lithographic cell LC may also include apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

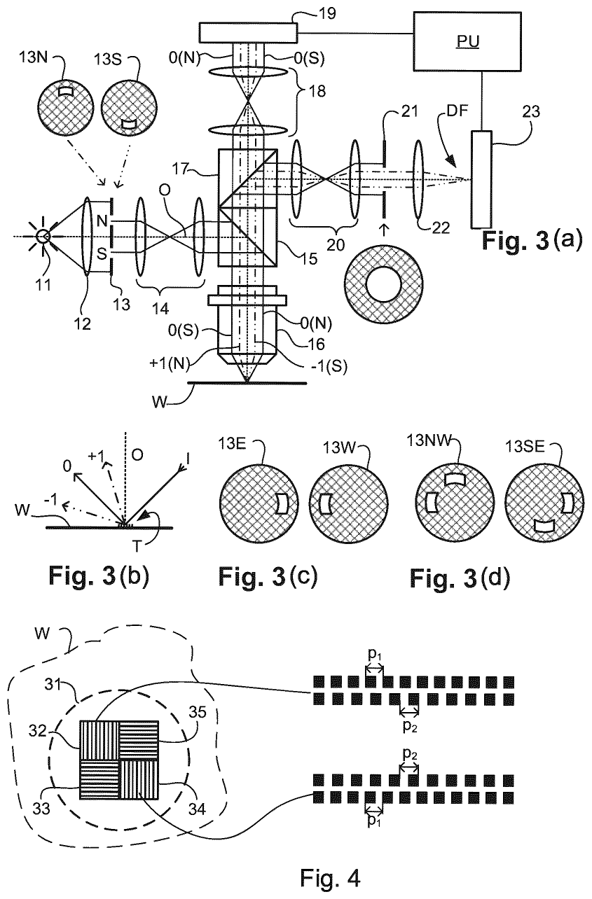

A metrology apparatus suitable for use in embodiments of the invention is shown in FIG. 3(a). A target T and diffracted rays of measurement radiation used to illuminate the target are illustrated in more detail in FIG. 3(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures, such as those which enable simultaneous illumination and detection from two opposing directions in combination with optical wedges to separate the resultant images. The rest of the pupil plane is desirably dark as any unnecessary light outside the desired illumination mode will interfere with the desired measurement signals.

As shown in FIG. 3(b), target T is placed with substrate W normal to the optical axis O of objective lens 16. The substrate W may be supported by a support (not shown). A ray of measurement radiation I impinging on target T from an angle off the axis O gives rise to a zeroth order ray (solid line O) and two first order rays (dot-chain line +1 and double dot-chain line −1). It should be remembered that with an overfilled small target, these rays are just one of many parallel rays covering the area of the substrate including metrology target T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the targets and the illumination angles can be designed or adjusted so that the first order rays entering the objective lens are closely aligned with the central optical axis. The rays illustrated in FIGS. 3(a) and 3(b) are shown somewhat off axis, purely to enable them to be more easily distinguished in the diagram.

At least the 0 and +1 orders diffracted by the target T on substrate W are collected by objective lens 16 and directed back through beam splitter 15. Returning to FIG. 3(a), both the first and second illumination modes are illustrated, by designating diametrically opposite apertures labeled as north (N) and south(S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled −1(S)) are the ones which enter the lens 16.

A second beam splitter 17 divides the diffracted beams into two measurement branches. In a first measurement branch, optical system 18 forms a diffraction spectrum (pupil plane image) of the target on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the −1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

The particular forms of aperture plate 13 and field stop 21 shown in FIG. 3 are purely examples. In another embodiment of the invention, on-axis illumination of the targets is used and an aperture stop with an off-axis aperture is used to pass substantially only one first order of diffracted light to the sensor. In yet other embodiments, 2nd, 3rd and higher order beams (not shown in FIG. 3) can be used in measurements, instead of or in addition to the first order beams.

In order to make the measurement radiation adaptable to these different types of measurement, the aperture plate 13 may comprise a number of aperture patterns formed around a disc, which rotates to bring a desired pattern into place. Note that aperture plate 13N or 13S can only be used to measure gratings oriented in one direction (X or Y depending on the set-up). For measurement of an orthogonal grating, rotation of the target through 90° and 270° might be implemented. Different aperture plates are shown in FIGS. 3(c) and (d). The use of these, and numerous other variations and applications of the apparatus are described in prior published applications, mentioned above.

It is known to use an apparatus such as illustrated in FIG. 3(a) to measure overlay. To achieve this, overlay targets may be printed on a wafer in two layers. One method of overlay metrology (sometimes referred to as micro-diffraction based overlay (μDBO) infers overlay from an asymmetry imbalance in complementary diffraction orders from targets comprising a respective grating in each layer. Typically, in μDBO the gratings have the same single pitch in each layer, though there may be an imposed bias between the two targets.

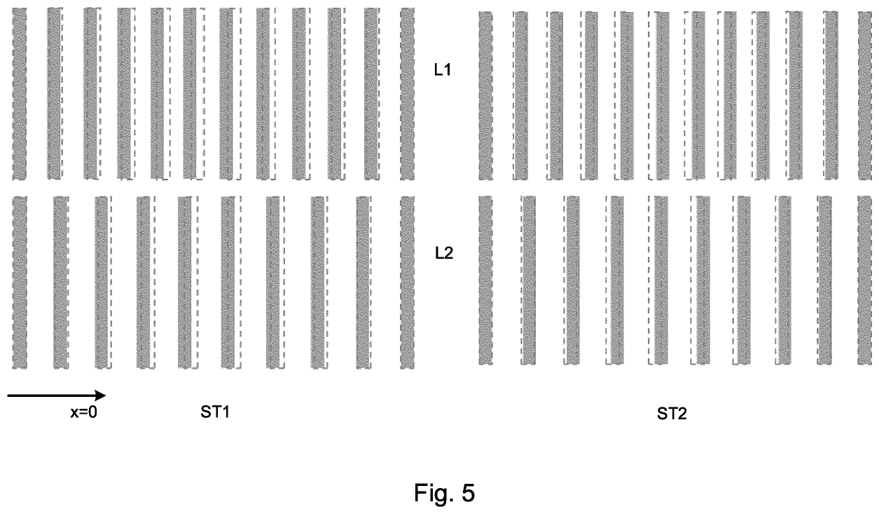

FIG. 4 is an example target on a wafer W which may be measured using an alternative known diffraction based overlay (DBO) metrology method. Such a metrology method may be overfilled such that the full target is captured within the measurement spot 31. In this DBO metrology method, the measured asymmetry signal may be a phase difference asymmetry from a pair of complementary sub-targets (a first type sub-target or “M pad” and a second type sub-target or “W pad”). In the example target shown, there are two such pairs of sub-targets, a first pair 32, 34 oriented in a first direction of the substrate plane and a second pair 33, 35 oriented in a second direction of the substrate plane. Each sub-target comprises overlaid periodic structures or gratings in respective layers for which an overlay value is to be measured. In contrast to the more common μDBO target (where the pitches are the same per layer), a sub-target such as illustrated in FIG. 4 has gratings of different pitches in each of the two layers.

More specifically a target such as illustrated in FIG. 4 comprises an arrangement of two different types of sub-targets (e.g., per direction): an “M pad” or “M sub-grating” 34, 35 which comprises a bottom grating having a smaller pitch p₁ than that of a top grating p₂, and a “W pad” or “W sub-grating” 32, 33 which has these gratings reversed (i.e., it may have the same pitches as the M pad but with the larger pitch p₂ in the top layer, although strictly speaking the two sub-targets do not need to have the same pitches). This is shown in the cross-section detail of one of these pairs 32, 34. In this manner, the target bias changes continuously along each target. The overlay signal is encoded in the resultant imaged Moiré patterns or intensity fringes (e.g., from dark field images of diffracted radiation from the sub-targets). A phase can be measured from each image from the position of the fringes within a target region of interest. Note that the actual arrangement of these sub-targets may vary from shown.

In such a method, an asymmetry signal A may be defined as the phase difference between a diffraction order from an “M pad” and a corresponding diffraction order from a “W pad”, e.g., A=(φ_{M}−φ_{W})+1 (e.g., sometimes referred to as the normal images) or (φ_{M}−φ_{W})₋₁ (e.g., sometimes referred to as the complementary images), where (φ_{M}−φ_{W})₊₁, (φ_{M}−φW)₋₁ are the measured phase difference between the “M pad” and “W pad” of the +1 diffraction order and −1 diffraction order respectively (using other diffraction orders are possible). Optionally a sum may be taken over both diffraction orders of a complementary diffraction order pair: e.g., A=(φ_{M}−φ_{W})₊₁+ (φ_{M}−φ_{W})₋₁. As such, it can be appreciated that the concepts described herein are applicable to different types of asymmetry signal. This measurement principle is described in Matsunobu et al, Novel diffraction-based overlay metrology utilizing phase-based overlay for improved robustness, Proc. SPIE 11611, Metrology, Inspection, and Process Control for Semiconductor Manufacturing XXXV, 1161126 (22 Feb. 2021), which is incorporated herein by reference.

Conventionally for such targets, the overlay OV can be extracted from the phase differences between the M pad and W pad target images, e.g., Fourier plane images from a +1 diffraction order and −1 diffraction order respectively, according to the following equation:

$$OV = \frac{1}{4 π} \frac{{p}_{1} {p}_{2}}{{p}_{2} + {p}_{1}} [ {( {ϕ}_{M} - {ϕ}_{W} )}_{+ 1} + {( {ϕ}_{M} - {ϕ}_{W} )}_{- 1} ] \qquad ( 1 )$$

although, as already mentioned, the phase signal in the square bracket may also be only one of (φ_{M}−φ_{W})₊₁ or (φ_{M}−φ_{W})₋₁.

A μDBO target uses only a single pitch, while the alternative DBO target illustrated in FIG. 4 uses only two pitches. As a result, (single wavelength) radiation diffracted from such targets having one or two pitches will only diffract to one or two angles thereby probing the optical system (and processing sensitivity) at one or two distinct locations. Any aberrations/errors present at these locations are very difficult to separate from the measurement itself. As such, optical aberrations/errors may adversely affect the accuracy of the measurement.

To address this issue a new measurement method and target design is proposed, for which the measured signal will be more robust to various errors often encountered in an optical system. The proposed target comprises two or more gratings, each having a chirped pitch, i.e., a pitch which spatially varies (e.g., monotonically) along the direction of periodicity. The measurement method may infer overlay (or other parameter of interest) from the Moiré pitch (e.g., more specifically a change of Moiré pitch); i.e., the pitch of Moiré fringes which form as a result of overlaid chirped pitches of the two or more gratings. Note that this measurement technique differs in principle to known measurement techniques of the FIG. 4 type target. In the known technique, overlay is inferred from the fringe phase of Moiré fringes, rather than fringe pitch used in the present method.

FIG. 5 illustrates such a target (formed by the solid filled bars) comprising respective gratings in a first layer L1 and second layer L2, having respectively a first chirped pitch and second chirped pitch. A target may comprise a pair of sub-targets ST1, ST2 with mirror-symmetry e.g., as analogous to the MW-pads of the FIG. 4 type target. For reference, the dotted line shows a conventional FIG. 4 type target where the respective gratings each have a constant pitch along their length.

In an embodiment, the chirp in a first grating of the target (e.g., the top grating in layer L1) may have a linear chirpiness in (at least a portion of the) direction of periodicity. However, this is not essential and other (e.g., monotonical) continuous chirpiness may be introduced, e.g., a higher order polynomial or exponential pitch variation. Chirpiness describes the rate of change of the pitch/frequency over the grating along the direction of periodicity.

It is known that Moiré fringes will be created from two overlaid gratings having respective pitches p₁, p₂, having a Moiré-pitch p_{M} (pitch or frequency of the Moiré fringes) described by (Equation 1):

$${p}_{M} = \frac{{p}_{1} {p}_{2}}{\vert {p}_{1} - {p}_{2} \vert}$$

as such, if p₁ is the first starting pitch of the chirped first grating in layer L1 and p₂ is the second starting pitch of the chirped second grating in layer L2, then Equation 1 will describe local Moiré-pitch at beginning of the target (position x=0)

The pitches may comprise a pitch variation/chirpiness which has been chosen such that, when the top and bottom grating are perfectly aligned (i.e., overlay OV=0), the Moiré-pitch p_{M} is substantially constant along the target (for all x, at least within a region of interest; for example a central region of the target away from edges). This concept can be further extended, such that the pitches are chosen to provide no Moiré-pitch variation over the target (e.g., region of interest) for both overlay and the unknown pitch-shift due to illumination/stack dependency (a₀=0).

Assuming starting pitches for the respective gratings p₁, p₂ and a (linear) chirpiness pₛₗₒₚₑ₁ for the first grating, where chirpiness describes the rate of Moiré-pitch/frequency change, this yields the following equation for the chirpiness pₛₗₒₚₑ₂ for the bottom-grating (Equation 2):

$${p}_{slope 2} = \frac{{p}_{slope 1} \cdot {p}_{2}^{2}}{{p}_{1}^{2} + {p}_{slope 1} \cdot ( {p}_{1} - {p}_{2} )}$$

It can be appreciated that this may differ when the chirpiness in the first grating is non-linear (e.g., pₛₗₒₚₑ₁ may be replaced by a suitable function).

Based on this, the first grating local pitch p₁ₓ at position x is given by (Equation 3):

p₁ₓ=p₁+pₛₗₒₚₑ₁·(a₀+OV+x)
and the second grating local pitch p₂ₓ at position x is given by (Equation 4):

$${p}_{2 x} = {p}_{2} + \frac{{p}_{slope 1} \cdot {p}_{2}^{2} \cdot x}{{p}_{1}^{2} + {p}_{slope 1} \cdot x \cdot ( {p}_{1} - {p}_{2} )} ;$$

this ensures a substantially constant Moiré-pitch for OV=0 and a₀=0 according to Equation 1.

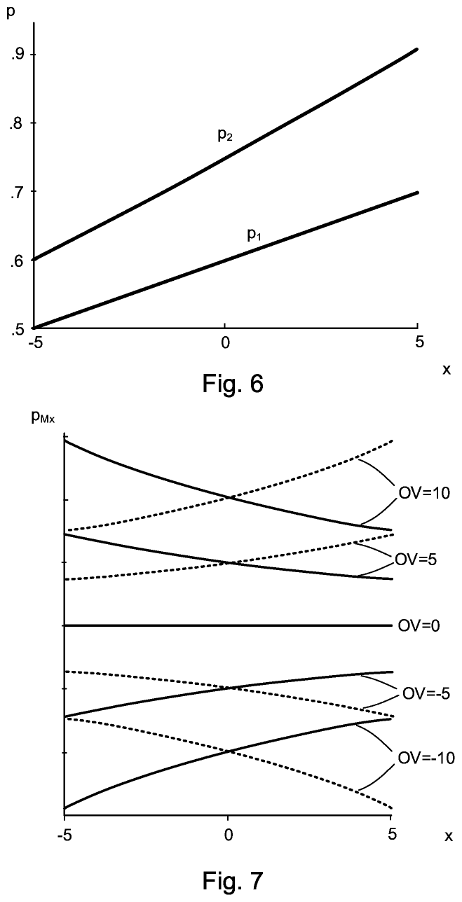

FIG. 6 is a plot of grating pitch p against position x on the target for the first grating p₁ and the second grating p₂ (both axes in μm) for a purely exemplary target (or sub-target). In this example the starting pitch of the first grating is p₁=0.5 μm and linearly increases to 0.7 μm over 10 μm of the target (i.e., pₛₗₒₚₑ₁=0.02), where the target center is defined as 0 μm (for convenience only). The second starting pitch of the second grating p₂=0.6 μm in this example, and pₛₗₒₚₑ₂ is calculated according to Equation 2.

When the gratings are no longer aligned (OV≠0 and/or a₀≠0), the local Moiré-pitch p_{Mx} at position x will change as a function of overlay OV and pitch-shift do due to illumination/stack dependency (Equation 5):

$${p}_{Mx} = \frac{\begin{matrix}( {p}_{1} + {p}_{slope 1} \cdot ( {a}_{0} + OV + x ) ) \cdot \\ ( {p}_{2} + \frac{{p}_{slope 1} \cdot {p}_{2}^{2} \cdot x}{{p}_{1}^{2} + {p}_{slope 1} \cdot x \cdot ( {p}_{1} - {p}_{2} )} )\end{matrix}}{\begin{matrix}{p}_{1} - {p}_{2} + {p}_{slope 1} \cdot ( {a}_{0} + OV + x ) - \\ \frac{{p}_{slope 1} \cdot {p}_{2}^{2} \cdot x}{{p}_{1}^{2} + {p}_{slope 1} \cdot x \cdot ( {p}_{1} - {p}_{2} )}\end{matrix}}$$

After a first order Taylor-expansion approximation, this yields at x=0 (Equation 6):

$${p}_{Mx} = - OV \cdot {p}_{2} \cdot ( \frac{{p}_{slope 1}}{{p}_{1} - {p}_{2} + {a}_{0} \cdot {p}_{slope 1}} - \frac{{p}_{slope 1} \cdot ( {p}_{1} + {a}_{0} \cdot {p}_{slope 1} )}{{( {p}_{1} - {p}_{2} + {a}_{0} \cdot {p}_{slope 1} )}^{2}} ) - \frac{{p}_{2} \cdot ( {p}_{1} + {a}_{0} \cdot {p}_{slope 1} )}{{p}_{1} - {p}_{2} + {a}_{0} \cdot {p}_{slope 1}}$$

It can be appreciated that, for the x=0 and a₀=0 case, Equation 6 becomes (Equation 7):

$${p}_{Mx} = - \frac{{p}_{1} {p}_{2}}{{p}_{1} - {p}_{2}} - OV \cdot {p}_{2} \cdot ( \frac{{p}_{slope 1}}{{p}_{1} - {p}_{2}} - \frac{{p}_{1} \cdot {p}_{slope 1}}{{( {p}_{1} - {p}_{2} )}^{2}} )$$

which shows that the local Moiré-pitch in the absence of stack effects comprises the standard Moiré relationship based on the starting pitches (i.e., Equation 1) and an additional overlay dependent term which disappears for zero overlay.

Based on the above, local overlay OVₓ at position x, can be determined by (Equation 8):

$${OV}_{x} = - \frac{2 {p}_{1}^{2} \cdot ( {p}_{Mx} \cdot {p}_{1} - {p}_{Mx} \cdot {p}_{2} ) + {p}_{1} {p}_{2}}{{p}_{slope 1} \cdot ( {p}_{Mx} \cdot {p}_{1}^{2} + {p}_{1}^{2} \cdot {p}_{2} )}$$

Note that this has been averaged over two complementary diffraction orders (e.g., +1 and −1 orders) such that the nuisance term do drops out. The local overlay OV can be calculated directly from the measured Moiré-pitch p_{Mx} and known parameters of the target p₁, P2, pₛₗₒₚₑ₁.

As such, a measurement method may comprise measuring the local Moiré-pitch for at least one diffraction order from a target (optionally comprising a pair of mirror-reversed sub-targets), and using Equation 8 to determine overlay from this measured local Moiré-pitch (as well as the known target parameters as described). More specifically, the method may comprise in an embodiment: illuminating the target with measurement illumination, imaging at least one diffraction order from the target, identifying a region of interest within the target image, determining a local Moiré-pitch value from the image (e.g., per diffraction order) and determining the local overlay from the local Moiré-pitch value. Determining the local Moiré-pitch may comprise determining a center of target and determining the local Moiré-pitch at this target center. The target center may be the position at which the local Moiré-pitch is the same for each of a pair of mirror-reversed sub-targets. The target center may also be determined by reference to a base pitch formed from two chirped pitches in a single layer (in such an embodiment, the target can be a single sub-target rather than a pair of mirror-reversed sub-targets). Many of these aspects will be described in further detail below.

The local Moiré-pitch used in Equation 8 may be the local Moiré-pitch for a single order or average local Moiré-pitch from a complementary pair of orders. As such, p_{Mx} may be the local Moiré-pitch as observed from a single order or the local Moiré-pitch when averaged over complementary pair of diffraction orders (e.g., the +1 order and −1 order). Averaging over the diffraction orders addresses the issue of unknown pitch-shift due to illumination/stack dependency do. Any stack thickness will introduce an additional change in pitch response. The diffracted signal from top and bottom grating will interact with a different part of the grating depending on the stack thickness. This will break the ideal symmetry around overlay OV=0. The normal and complementary detected signals (+1 orders) will show an opposite response to the stack thickness. The average of the normal and complementary detected pitches should correct for the impact of stack thickness.

More generally, the local Moiré-pitch value may be averaged over any complementary pair of detected orders, i.e., not necessarily diffraction orders. For example, the target is compatible with zeroth order detection as may be used, for example, in image based overlay (IBO). An off-axis illumination/detection will introduce stack-dependence and a pair of complementary illumination angles may be used (e.g., simultaneously or sequentially) to compensate for this effect. In such an arrangement, the complementary pair of detected orders may comprise the resultant detected orders from the pair of complementary illumination angles.

FIG. 7 is a plot of local Moiré-pitch p_{Mx} against position on the target x for a plurality of different overlay values (−10 nm, −5 nm, 0, 5 nm and 10 nm are the examples shown). The mirror-symmetric pads are plotted respectively with solid and dashed lines. As can be seen, there is a different relationship between Moiré-pitch and target position for each overlay value (with opposite response for the mirror symmetric pads. As has already been described, the local Moiré-pitch p_{Mx} is constant for zero overlay. The sensitivity of Moiré-pitch p_{Mx} to overlay may be tuned by altering the start/end pitches of the chirped grating(s).

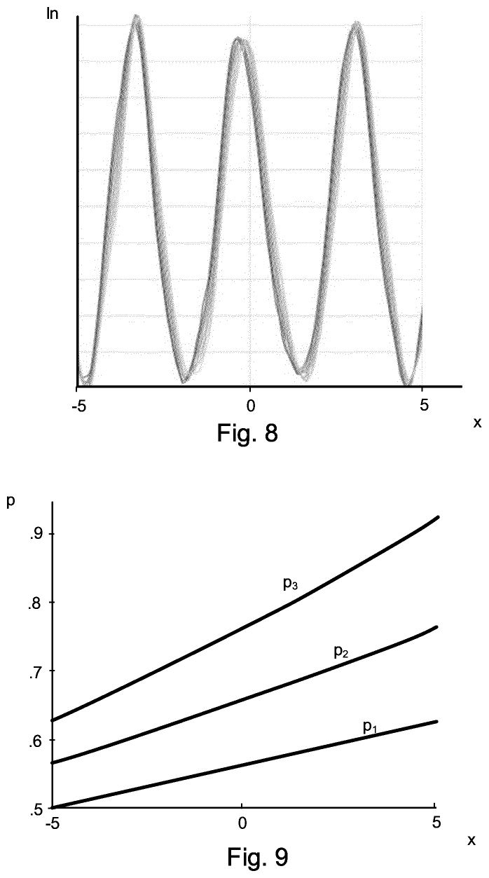

FIG. 8 is a plot of intensity In against target position x for a plurality of different overlay values (each line relates to a different overlay value). Any suitable known pitch detection method may be used to detect the local pitch (frequency) of the Moiré fringes. Such pitch detection methods may comprise time domain and/or frequency domain methods. Such methods may comprise detecting zero-crossings of the signal (e.g., determining the zero-crossing rate or distance between zero crossings). Other methods may include Fourier methods such as Fast Fourier Transform FFT methods or any other suitable periodogram methods. In another alternative, spectral/temporal pitch detection algorithms may be used, such as those based upon a combination of time domain processing using an autocorrelation function (e.g., normalized cross correlation), and frequency domain processing utilizing spectral information to identify the pitch. Such methods are well known to the skilled person and will not be described in detail here.

The local Moiré-pitch p_{Mx} used to determine overlay may relate to a particular (e.g., single) position on the target (or sub-target), for example the Moiré-pitch p_{Mx} at the target center may be used in Equation 8. Any deviation in the assumption of the target center will impact the overlay estimation. Methods for determining the Moiré-pitch at the target center will now be described.

In a first approach, already briefly described in relation to FIG. 5, two mirrored sub-targets (e.g., similar to the M/W sub-targets described in relation to FIG. 4) can be used, each having opposite pitch-response. For convenience (and easier analysis) these target-pads can be placed above (instead of next to) each other (i.e., if the target plane is x/y and the direction of periodicity is x, then the sub-targets may be adjacent in y). In this first approach, the location on each sub-target having equal Moiré-pitch (e.g., the crossing points of the non-zero overlay relationships in FIG. 7) can be assumed to be the target-center (e.g., per detected ±1st order image). This equal Moiré-pitch value may be used in Equation 8 to derive overlay.

Another method may comprise forming the target from three gratings, each having a continuously varying pitch (e.g., and different starting pitch), but with two of the gratings printed interlaced in a single layer (printed in one exposure). In doing this, the resulting Moiré-pitch between the gratings formed in a single layer will have no overlay dependence and therefore can be used as a position reference (base pitch). As such the two interlaced gratings in a single layer may be used as a reference structure for the overlay measurement. This position reference may be used to determine the target-center for local Moiré-pitch determination; having no overlay dependency, its Moiré-pitch will depend only on known target parameters.

It can be appreciated that such a target will actually generate three Moiré-pitches (ignoring the sum-frequencies), each formed from respective pairs of the gratings. By way of a specific example, if there are three pitches p₁, p₂, p₃; e.g., arranged such that gratings starting with pitch p₁ and pitch p₃ are interlaced in the same layer and a grating with pitch p₂ is in a separate layer (although other arrangements are equally possible), then there will be a (overlay independent) base frequency resulting from interaction of the pitch p₁ and pitch p₃ gratings and two signal frequencies resulting from the interaction of the pitch p₁ and pitch p₂ gratings and the interaction of the pitch p₂ and pitch p₃ gratings respectively.

The pitch of the third chirped grating may be chosen such that the local Moiré-pitch is constant for zero overlay (e.g., and zero pitch-shift due to illumination/stack dependency). This may be achieved using the same techniques as already described, e.g., using Equation 2 to determine change in pitch pₛₗₒₚₑ₃ for the third grating based on the grating parameters of the second grating (i.e., with p₂, p₃ and pₛₗₒₚₑ₂ in place of p₁, p₂ and pₛₗₒₚₑ₁ respectively, where p₃ is the starting pitch of this third grating). Equation 2 can also be used to determine pₛₗₒₚₑ₂ based on the first pitch parameters as before. FIG. 9 is a plot of grating pitch p against position x on the target for such a target.

The measured spatial (intensity) response along the grating can be analyzed via frequency demodulation (e.g., using similar techniques as used in FM-radio) as a signal trace. In this respect the two gratings in a single layer (reference layer or zero layer) generates a base frequency (i.e., the base pitch) modulated by the two signal frequencies. The detected phase of the zero-layer can be used as position reference for the target-center.

It can be appreciated that it is also possible to have interlaced (double-chirp-pitch) gratings in both layers. For example, (starting from the example just described) a fourth chirped grating may be provided with a starting pitch p₄ interlaced in the same layer as the grating with pitch p₂. The change in pitch pₛₗₒₚₑ₄ can be determined as already described based on the grating parameters of the third grating or the second grating. It is also possible to have interlaced three-chirp-pitch gratings in one or both layers. More generally, any number of interlaced gratings may be comprised in any one or more layers.

Optionally, the target of any of the embodiments described herein may comprise a pitch bias to improve sensitivity in detecting pitch changes, impact of stack thickness and to mitigate the non-linear response. This is a known technique in for example μDBO metrology. This pitch bias may comprise biasing the pitch of each sub-target of a pair of sub-targets such that respectively each sub-target does not have a substantially constant Moiré pitch for zero overlay, but where the averaged Moiré pitch over the pair of sub-targets has a substantially constant Moiré pitch for zero overlay.

As is known, a target may comprise a sub-target or mirrored pair of sub-targets per (perpendicular) direction the substrate plane, e.g., x targets and y targets.

In an embodiment, the measured response (and any deviation from an expected response) over all the chirped pitches (and further optionally over multiple wavelengths and/or targets) can be used as input for correction of optical/processing disturbances.

In an embodiment, a tool induced shift (TIS) correction based on wafer rotation (or effective wafer rotation) may be performed using known TIS correction methods, e.g., to capture any magnification errors. As such rotation of the wafer or measurement from two opposing directions may be performed (the latter can be done simultaneously) to obtain respective images, from which a difference may be determined. This difference may arise as a result of TIS and therefore can be used as a correction for the measurements.

It can be appreciated that the concepts disclosed herein do not use the phase of the Moiré-fringes; however this phase also comprises overlay information. The known processing methods used with FIG. 4 type target can also be used here, when zoomed onto a small portion of the target where it can be assumed that the pitches are constant, e.g. two lines per grating. This additional overlay information may be used to make any overlay inference from the Moiré-fringes more robust.

The proposed target layout depicted in FIG. 5 is shown as an example, and other target layouts are possible within the scope of this disclosure, including inter alia: interlaced targets and/or 2D targets.

While the overlay inference method disclosed herein is based on using Equation 8 to infer overlay from a measured Moiré-pitch value, other methods are possible using the methods disclosed herein. For example, the Moiré-pitch along the target (Moiré-pitch vs position x) can be modeled and this model (shape and/or slope) compared to calibration models previously determined in a calibration phase to infer overlay.

Further embodiments are described in below numbered clauses:
1. A method of metrology, comprising: obtaining metrology data relating to measurement of a target comprising at least a first grating in a first layer and a second grating in a second layer, wherein the first grating has a first chirped pitch starting with a first starting pitch and the second grating has a second chirped pitch starting with a second starting pitch, the first grating and second grating substantially overlapping, and the first chirped pitch and second chirped pitch being different, so as to generate at least one parameter of interest dependent Moiré-pitch when measured; determining a parameter of interest from said at least one parameter of interest dependent Moiré-pitch described in said metrology data.
2. A method according to clause 1, wherein said first chirped pitch comprises a linear chirpiness.
3. A method according to clause 1 or clause 2, wherein said first starting pitch and second starting pitch are different.
4. A method according to any preceding clause, wherein said determining a parameter of interest comprises: determining at least one local Moiré-pitch value, said local Moiré-pitch value comprising a value for the Moiré-pitch for at least one position along a direction of periodicity of the target; and determining a parameter of interest from said at least one local Moiré-pitch value.
5. A method according to clause 4, wherein the first chirped pitch and second chirped pitch are configured such that the local Moiré-pitch is substantially constant within at least a region of interest for all positions along said direction of periodicity on the target, or for all positions along said direction of periodicity on the target when averaged over a pair of sub-targets comprised within the target, when at least said parameter of interest is zero.
6. A method according to clause 4, wherein the first chirped pitch and second chirped pitch are configured such that the local Moiré-pitch is substantially constant within at least a region of interest for all positions along said direction of periodicity on the target, or for all positions along said direction of periodicity on the target when averaged over a pair of sub-targets comprised within the target, when at least each of said parameter of interest and a pitch-shift due to illumination and/or stack dependency are both zero.
7. A method according to any of clauses 4 to 6, wherein said determining a parameter of interest from said at least one local Moiré-pitch value comprises determining said parameter of interest from the local Moiré-pitch value, the first starting pitch, the second starting pitch and the chirpiness of the first chirped pitch.
8. A method according to any of clauses 4 to 7, wherein said at least one local Moiré-pitch value relates to a center position on said target.
9. A method according to clause 8, wherein said target comprises a pair of mirror symmetric sub-targets, and said center position comprises the position at which the local Moiré-pitch value is the same for both of said pair of mirror symmetric sub-targets.
10. A method according to clause 9, wherein said target comprises one or more additional gratings, arranged such that the first grating in the first layer is interlaced with at least one of the one or more additional gratings and/or the second grating in the second layer is interlaced with at least one of the one or more additional gratings, each additional grating comprising a chirped pitch.
11. A method according to clause 10, wherein said one or more additional gratings comprises a third grating comprising a third chirped pitch starting with a third starting pitch, said third grating being interlaced with said first grating in the first layer or said second grating in the second layer, said third grating and the first grating or second grating in the same layer together forming a reference structure providing a reference Moiré-pitch.
12. A method according to clause 11, wherein the method comprises determining the center position with relation to the reference Moiré-pitch.
13. A method according to clause 11 or 12, comprising using frequency demodulation to demodulate at least one said parameter of interest dependent Moiré-pitch from the reference Moiré-pitch.
14. A method according to any of clauses 4 to 6, wherein said determining a parameter of interest comprises: comprising a plurality of local Moiré-pitch values for different positions along the target; and determining said parameter of interest from a variation of the local Moiré-pitch values with target position.
15. A method according to any preceding clause, wherein said metrology data relates to both diffraction orders of a complementary pair of detected orders; and said at least one local Moiré-pitch value comprises an average at least one local Moiré-pitch value, averaged over said complementary pair of detected orders.
16. A method according to any preceding clause, wherein said target, or each sub-target comprised within said target, comprises a pitch bias.
17. A method according to any preceding clause, wherein said determining a parameter of interest comprises additionally determining a phase of said at least one parameter of interest dependent Moiré-pitch; and using said phase, in addition to said parameter of interest dependent Moiré-pitch, in determining a parameter of interest.
18. A method according to any preceding clause, wherein said metrology data comprises one or more images comprising Moiré fringes having said at least one parameter of interest dependent Moiré-pitch.
19. A method according to in clause 18, comprises illuminating said target and imaging at least one diffraction order from said target to obtain said one or more images.
20. A method according to any preceding clause, comprising: determining a process correction based on said value for a parameter of interest.
21. A method according to clause 20, comprising performing a subsequent exposure action based on the process correction.
22. A method according to any of preceding clause, wherein said parameter of interest is overlay.
23. A computer program comprising program instructions operable to perform the method of any preceding clause, when run on a suitable apparatus.
24. A non-transient computer program carrier comprising the computer program of clause 23.
25. A processing arrangement comprising: a non-transient computer program carrier comprising a computer program comprising program instructions operable to perform the method of any of clauses 1 to 22, when run on a suitable apparatus; and a processor operable to run the computer program comprised on said non-transient computer program carrier.
26. A metrology apparatus comprising: a support for a substrate; an optical system for illuminating said structure with measurement radiation; a detector for detecting the measurement radiation scattered by the structure; and the processing arrangement of clause 25.

While the targets described above are metrology targets specifically designed and formed for the purposes of measurement, in other embodiments, properties may be measured on targets which are functional parts of devices formed on the substrate. Many devices have regular, grating-like structures. The terms ‘target grating’ and ‘target’ as used herein do not require that the structure has been provided specifically for the measurement being performed. Further, pitch P of the metrology targets is close to the resolution limit of the optical system of the scatterometer, but may be much larger than the dimension of typical product features made by lithographic process in the target portions C. In practice the lines and/or spaces of the overlay gratings within the targets may be made to include smaller structures similar in dimension to the product features.

In association with the physical grating structures of the targets as realized on substrates and patterning devices, an embodiment may include a computer program containing one or more sequences of machine-readable instructions describing methods of measuring targets on a substrate and/or analyzing measurements to obtain information about a lithographic process. This computer program may be executed for example within unit PU in the apparatus of FIG. 3 and/or the control unit LACU of FIG. 2. There may also be provided a data storage medium (e.g., semiconductor memory, magnetic or optical disk) having such a computer program stored therein. Where an existing metrology apparatus, for example of the type shown in FIG. 3, is already in production and/or in use, the invention can be implemented by the provision of updated computer program products for causing a processor to perform the methods disclosed herein.

While the embodiments disclosed above are described in terms of diffraction based overlay measurements (e.g., measurements made using the second measurement branch of the apparatus shown in FIG. 3(a)), in principle the same models can be used for pupil based overlay measurements (e.g., measurements made using the first measurement branch of the apparatus shown in FIG. 3(a)). Consequently, it should be appreciated that the concepts described herein are equally applicable to diffraction based overlay measurements and pupil based overlay measurements.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1.-11. (canceled)

12. A substrate comprising at least one target with each the of the at least one target comprises:
at least a first grating in a first layer and a second grating in a second layer, wherein the first grating has a first chirped pitch starting with a first starting pitch and the second grating has a second chirped pitch starting with a second starting pitch, wherein the first grating and second grating substantially overlap, and the first chirped pitch and second chirped pitch are different, so as to generate at least one parameter of interest dependent Moiré-pitch when measured.

13. The substrate of claim 12, wherein the first chirped pitch comprises a linear chirpiness.

14. The substrate of claim 12, wherein the first starting pitch and second starting pitch are different.

15. The substrate of claim 12, wherein the first chirped pitch and second chirped pitch are configured such that the Moiré-pitch is substantially constant within at least a region of interest for all positions along a direction of periodicity on the target, or for all positions along the direction of periodicity on the target when averaged over a pair of sub-targets comprised within the target, when the at least one parameter of interest is zero.

16. The substrate of claim 12, wherein the first chirped pitch and second chirped pitch are configured such that the Moiré-pitch is substantially constant within at least a region of interest for all positions along a direction of periodicity on the target, or for all positions along the direction of periodicity on the target when averaged over a pair of sub-targets comprised within the target, when the at least one parameter of interest and a pitch-shift due to illumination and/or stack dependency are both zero.

17. The substrate of claim 12, wherein the target comprises a pair of mirror symmetric sub-targets.

18. The substrate of claim 12, wherein the target comprises one or more additional gratings, arranged such that the first grating in the first layer is interlaced with at least one of the one or more additional gratings and/or the second grating in the second layer is interlaced with at least one of the one or more additional gratings, each additional grating comprising a chirped pitch

19. The substrate of claim 18, wherein the target comprises a third grating comprising a third chirped pitch starting with a third starting pitch, the third grating being interlaced with the first grating in the first layer or the second grating in the second layer, the third grating and the first grating or second grating in the same layer together forming a reference structure providing a reference Moiré-pitch when measured.

20. The substrate of claim 12, wherein the target, or each sub-target comprised within the target, comprises a pitch bias.

21. The substrate of claim 12, wherein the at least one parameter of interest is overlay.

22. A set of reticles comprising respective pattern structures configured to form at least one target on a substrate, and configured to manufacture a substrate according to claim 12.
